(19) United States
(12) Patent Application Publication
(10) Pub. No.: US 2018/0019309 A1
(43) Pub. Date: Jan. 18, 2018

(54) SEMICONDUCTOR DEVICE BASED ON WIDEBAND GAP SEMICONDUCTOR MATERIALS

(71) Applicant: Global Power Technologies Group, Inc., Lake Forest, CA (US)

(72) Inventors: Rahul Radhakrishnan, Lake Forest, CA (US); James Cooper, Santa Fe, NM (US)

(21) Appl. No.: 15/652,112

(22) Filed: Jul. 17, 2017

Related U.S. Application Data
(60) Provisional application No. 62/363,176, filed on Jul. 15, 2016.

(51) Int. Cl. H01L 29/16; H01L 29/20; H01L 21/02; H01L 21/04; H01L 29/78; H01L 29/778

(52) U.S. Cl. CPC H01L 29/1608; H01L 29/7839; H01L 29/7787; H01L 21/02104; H01L 21/045; H01L 29/2003

(57) ABSTRACT

Methods, systems, and devices are disclosed for implementing a semiconductor device having a transistor and a diode that are monolithically integrated. In one aspect, a semiconductor device is provided to include a substrate including semiconductor materials; a drift region formed over the substrate; doping region formed on a surface of the drift region and including a first impurity region and a second impurity region formed over the first impurity region; a body contact formed adjacent to the second impurity region; a Schottky region formed adjacent to the body contact such that the second impurity region and the Schottky contact are located on opposite sides of the body contact, the Schottky region contacting the drift region; and a gate region formed over the doping region.

### CROSS-REFERENCE TO RELATED APPLICATIONS

This patent document claims priorities to and benefits of U.S. Provisional Patent Application No. 62/363,176, filed on Jul. 15, 2016, entitled “MONOLITHICALLY INTEGRATED MOSFET AND ANTI-PARALLEL DIODE BASED ON WIDE BANDGAP SEMICONDUCTORS”. The entire content of the before-mentioned patent application is incorporated by reference as part of the disclosure of this application.

### TECHNICAL FIELD

This patent document relates to semiconductor circuits and technologies based on a wide bandgap semiconductor materials such as Silicon carbide (SiC) and other semiconductor materials.

### BACKGROUND

Semiconductor materials having wide bandgaps such as Silicon carbide (SiC) semiconductor materials and others can exist in various crystalline forms and can be used to construct a range of circuits and devices. Such semiconductor materials usually have bandgaps greater than 1.1V which is the bandgap of Silicon. For example, in comparison with the commonly used silicon, SiC materials possess properties such as a wide bandgap structure and higher breakdown field. These properties make SiC materials attractive for a wide range of circuits and applications including high power electronics.

A field-effect transistor (FET) is a transistor that uses an electric field to control the shape and in turn the conductivity of a channel of one type of charge carrier in a semiconductor material. FETs are unipolar transistors that involve single-carrier-type operation. FETs can be structured to include an active channel through which majority charge carriers, e.g., such as electrons or holes, flow from a source to a drain. The main terminals of a FET include a source, through which the majority carriers enter the channel; a drain, through which the majority carriers leave the channel; and a gate, the terminal that modulates the channel conductivity. For example, source and drain terminal conductors can be connected to the semiconductor through ohmic contacts. The channel conductivity is a function of the potential applied across the gate and source terminals.

### SUMMARY

The disclosed technology in this patent document provides a semiconductor device having a transistor and a diode that are monolithically integrated. The techniques suggested in this patent document allows to reduce component count, chip area, capacitance, cost, parasitic elements, etc. as compared to a case where the transistor is externally connected to the diode.

In one aspect, a semiconductor device is provided to include: a substrate including semiconductor materials; a drift region formed over the substrate; doping region formed on a surface of the drift region and including a first impurity region and a second impurity region formed over the first impurity region; a body contact formed adjacent to the second impurity region around an edge of the first impurity region; a Schottky region formed adjacent to the body contact such that the second impurity region and the Schottky region are located on opposite sides of the body contact, the Schottky region contacting the drift region; and a gate region formed over the doping region.

In some implementations, the first impurity region include a p-well region and the second impurity region includes an n+ source region. In some implementations, the first impurity region has a non-rectangular planar shape. In some implementations, the device further comprises a current spreading layer formed over the drift region and has a portion extending from the drift region to a level same as top surfaces of the doping region and the body contact. In some implementations, the first impurity region, the second impurity region, the body contact, and the Schottky region are arranged on first impurity region does not extend along an entire width of the device. In some implementations, the semiconductor materials have a bandgap wider than that of silicon and include SiC or GaN. In some implementations, the Schottky region is shorted to the body contact and the second impurity region. In some implementations, the doping region provides a channel region adjacent to the second impurity region along a first direction parallel to a surface of the substrate and between the gate region and the drift region along a second direction perpendicular to the first direction. In some implementations, the second impurity region is contained within the first impurity region. In some implementations, the first impurity region is structured to extend horizontally below the second impurity region and further extend to a surface of the Schottky surface.

In another aspect, a semiconductor device is provided to include: a transistor region having a gate region and a source region formed on a side of the gate region, the gate region including a gate formed over a first doping region, a second doping region, and a junction field effect transistor (JFET) region formed between the first doping region and the second doping region; and a diode region formed over the second doping region and a third doping region, the diode region including an Ohmic contact formed over the second doping region and the third doping region and a Schottky contact formed over an area between the second doping region and the third doping region; and a termination region surrounding the diode anode region and the transistor region.

In some implementations, the transistor region, the diode region, and the termination region are concentrically arranged in a same plane. In some implementations, the diode region is arranged between the transistor region and the termination region. In some implementations, the transistor region is arranged between the diode region and the termination region. In some implementations, the second doping region includes a first portion and a second portion that are included in the transistor region and the diode region, respectively. In some implementations, the first portion of the second doping region includes a n+ source region and the second portion of the second doping region includes a p+ body region. In some implementations, the first doping region includes a p-well and a n+ source region. In some implementations, the third doping region includes a p-well and a p+ body region.

In another aspect, a semiconductor device is provided to include a semiconductor substrate doped with a first-type conductivity with a first concentration; a drift region formed over the semiconductor substrate and has the first-type conductivity with a second concentration smaller than the first concentration, the drifting region including a first area and a second area that are adjacent each other; doping regions formed in the drift region to be spaced apart from one another, each doping region including a p-well region; a gate formed over the first area of the drift region; and a Schottky contact formed over the second area of the drift region, and wherein the doping region further includes heavily doped regions over the p-well regions such that a particular heavily doped region has the first-type conductivity or a second-type conductivity different from the first-type conductivity depending on whether the particular heavily doped region is located in the first area or the second area.

In some implementations, the drifting region further includes a third area over which a termination is provided. In some implementations, a junction field effect transistor (JFET) region is formed over the first area of the drift region. In some implementations, a current spreading layer is formed in the drift region to have the first-type conductivity. In some implementations, the device further comprises an ohmic contact between the gate and the Schottky contact and over the doping regions. In some implementations, the semiconductor substrate includes materials having a bandgap wider than that of silicon.

These and other aspects, implementations and associated advantages are described in greater detail in the drawings, the description and the claims.

### BRIEF DESCRIPTION OF THE DRAWINGS

FIG. 1 shows an example of a transistor which is included in a semiconductor device based on the disclosed technology.

FIG. 2 shows an example of a diode which is monolithically incorporated with the transistor of FIG. 1 to provide a semiconductor device based on the disclosed technology.

FIGS. 3A and 3B show a front view and a back view of an exemplary semiconductor device based on the disclosed technology.

FIG. 4A shows a cross sectional view of an exemplary semiconductor device based on the disclosed technology.

FIG. 4B shows another cross sectional view of an exemplary semiconductor device based on the disclosed technology.

FIG. 4C shows a top view of an exemplary semiconductor device based on the disclosed technology.

FIG. 5 shows a cross sectional view of an exemplary semiconductor device based on the disclosed technology.

FIG. 6 shows a top view of an exemplary semiconductor device based on the disclosed technology.

FIG. 7 shows a top view of another exemplary semiconductor device based on the disclosed technology.

### DETAILED DESCRIPTION

The disclosed circuits and techniques can be implemented to provide a semiconductor device based on wide bandgap semiconductors such as SiC, GaN and others. Implementations of the disclosed technology introduces a new device in which a transistor, for example, a planar MOSFET, i.e., DMOSFET, is monolithically integrated with an anti-parallel diode.

Power electronics have been developed over several decades, and power devices are being used in various technologies. To improve system efficiency and power density of the power devices, wide-bandgap materials such as silicon carbide (SiC) and gallium nitride (GaN) instead of silicon (Si) are being used. For example, a Metal-Oxide-Semiconductor Filed-Effect Transistor based on SiC (SiC-MOSFET) is a maturing technology which seeks to replace a Metal-Oxide-Semiconductor Filed-Effect Transistor based on Si (Si-MOSFET) and insulated gate bipolar transistor (IGBT) circuits based on Si in power switching applications. While SiC-MOSFETs can be configured to reduce the chip area and capacitance, certain implementations of such solutions can be more expensive than Si-MOSFETs and do not have a built-in low voltage drop diode. The built-in body-drain diode of Si-MOSFET has low forward voltage drop because of the narrow bandgap of Si, however the wide bandgap of SiC gives the body-drain diode of SiC MOSFETs a high forward voltage drop.

SiC-MOSFET is a prime candidate for inverters in electric vehicle (EV) chargers and drives, however, this application requires the switch to be connected to an anti-parallel diode to carry reverse current when the MOSFET is shut-off. The body diode of Si-MOSFET is reliable and has low voltage drop, which makes it ideal for EV applications. The SiC-MOSFET has an inherent body-diode, the operation of which is undesirable for reliable device operations. For example, the phenomenon of recombination-induced stacking faults in high-voltage p-n diodes in SiC has been shown to increase the forward voltage drop due to reduction of minority carrier lifetime. The body diode of SiC-MOSFET has 3× the on-state voltage drop of its Si counterpart. In some existing designs, the body diode being a bipolar device can also suffer from persisting limitations of SiC material that causes its bipolar on-state voltage drop to drift with stress. Hence, various existing designs co-pack a SiC-MOSFET with an anti-parallel SiC Schottky (unipolar) diode in an integrated package as a drop-in replacement for a Si-MOSFET by externally connecting the SiC-MOSFET to the diode through separate electric field termination.

SiC-MOSFETs co-packed with diode, however, may also lead to undesired results such as increase of component count, chip area, capacitance, cost, parasitic elements, etc. The techniques suggested in this patent document can address such undesired issues by monolithically integrating the SiC-MOSFET with a lower voltage drop unipolar diode. The chip area of SiC-MOSFETs with co-packed diodes tends to increase because separate electric field termination and dicing clearance at the edge of the die tend to be required for both the MOSFET and the diode, thus increasing cost. Parasitic inductances and capacitances are introduced in the power circuit when MOSFET is wired up with an anti-parallel diode. These parasitic components, which might necessitate larger area devices to handle the same current and voltage, can be reduced when MOSFET and diode are monolithically integrated. In some implementations, an anti-parallel diode, for example, anti-parallel Junction-Barrier Schottky (JBS) diode, is built into the SiC-MOSFET cell. In this case, the integrated SiC-MOSFET and the diode can form a power electronic building block, which reduces chip area, parasitic elements and capacitance. In addition, the techniques suggested in this patent document also allow flexible selection of the diode current capability as a proportion of the rated current of the MOSFET.

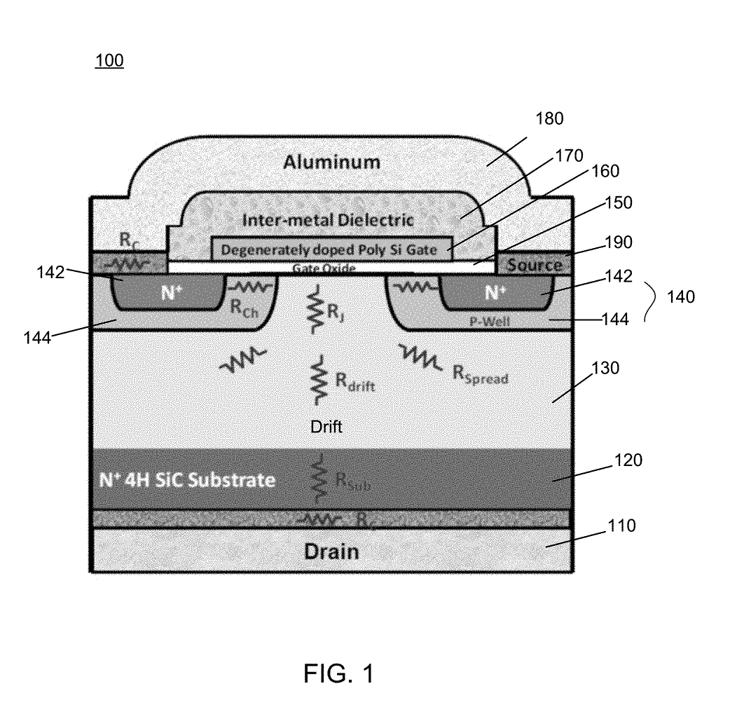

Various implementations of the disclosed technology will be explained with reference to the drawings. A semiconductor device suggested in this patent document has a transistor and a diode that are monolithically integrated. FIG. 1 shows a cross-section view of on exemplary transistor which is included in the semiconductor device. In FIG. 1, a planar MOSFET, i.e., DMOSFET, is illustrated as an example. In the exemplary DMOSFET 100 as shown in FIG. 1, a drain region 110 is disposed at one side of a SiC substrate 120 opposite to a drift region 130. Doping regions 140 are disposed at an interval on a surface of the drift region 130. Each doping region 140 includes a n+ region 142 and a p-well 144. The contact resistance, Rc, is also shown in FIG. 1 between the drain 110 and the SiC substrate 120 and between the n+ region 142 and the overlayer metal 180. In some implementations, heavy dose impurity implantations are performed to form the n+ region 142, and then the p-well 144 with retrograde profile are formed by impurity implantation. As an example, nitrogen may be used for the heavy dose impurity implantation and aluminum may be used for the retrograde profile impurity implantation. A junction field effect transistor (JFET) region is formed between the doping regions 140. A gate oxide material 150 and a gate poly 160 are formed over the surface of the draft region 130 and may include SiO₂, nitride-containing SiO₂ or Al₂O₃ by thermal oxidation, chemical vapor deposition (CVD) or atomic layer deposition (ALD). An interlayer dielectric layer 170 is formed to cover the gate poly 160 and may include tetraethyl-ortho-silicate (TEOS), boro-phospho-silicate-glass (BPSG), oxynitride, undoped silicate glass (USG) or silicon rich nitride (SRN). An over-layer 180 is deposited to form an electrode. Although FIG. 1 shows aluminum as material of the over-layer 180, other materials are also available. The source contact 190 is formed over the doping regions 140 and is located on both sides of the gate oxide 150. In the SiC DMOSFET 100 shown in FIG. 1, the n+ region 142 could either continue in the third dimension along the entire width of the device or it could be segmented and replaced with p+ implants for the body contact. In some implementations, the p-well regions 144 typically stretch along the entire width of the device. The DMOSFET 100 has an inherent P-N diode between the body (shorted to the source) and the drain 110, the junction being between the p-well 144 and N-epi 130 in FIG. 1. However, SiC P-N diode has quite high or very high forward voltage drop (˜4V). Incorporating the JBS diode 200 can reduce the body-drain diode voltage drop of DMOSFET 100 from ˜4V to ˜1.5V.

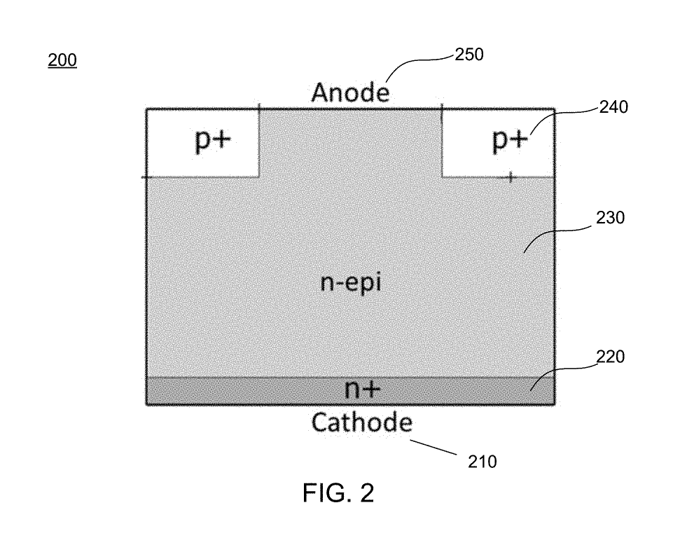

FIG. 2 shows a cross-sectional view of an example of an anti-parallel diode, a JBS diode, which is included in a semiconductor device and monolithically incorporated with the structure of FIG. 1. JBS diodes are designed to combine the low forward resistance and fast switching capability of Schottky diodes with the low reverse leakage currents of p-n diodes. The JBS diode is highly interdigitated with the MOSFET. In SiC JBS diodes, the turn-on voltage can be significantly reduced from ˜2.7V for p-n diodes to ˜1V for certain JBS diodes. Referring to FIG. 2, the JBS diode 200, which is monolithically incorporated with the MOSFET 100, has a cathode 210 and an anode 250 on two opposing sides, e.g., the bottom and the top, of the device 200, respectively. Between the cathode 210 and the anode 250, an n+ region 220 and an n-epi region 230 are formed. On both sides of a surface of the n-epi region 230, p+ regions 240 are formed, which provide a p+n junction integrated into the n-epi region 230.

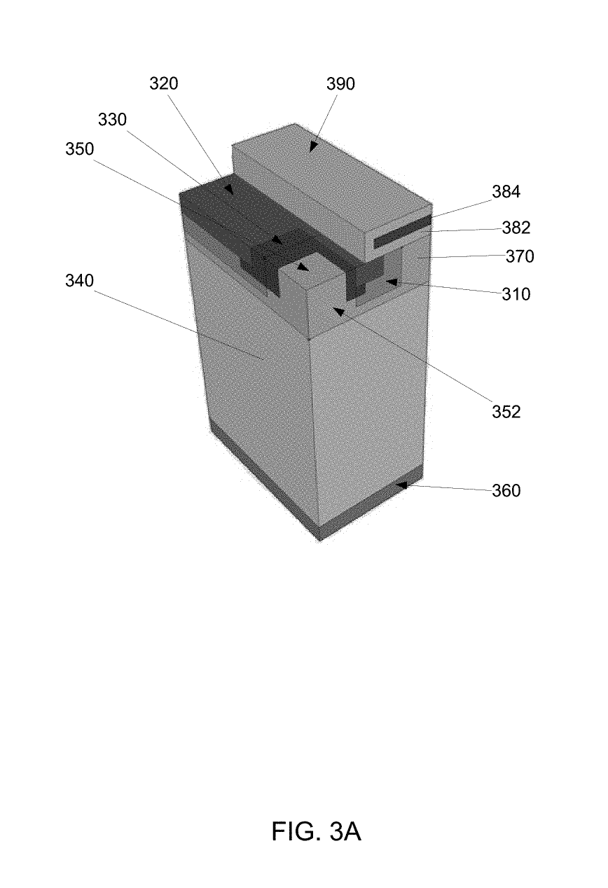

By incorporating the DMOSFET in FIG. 1 with the JBS diode in FIG. 2, the semiconductor device as suggested in this patent document is provided. FIGS. 3A and 3B show a front view and a back-view of an exemplary semiconductor device having a MOSFET monolithically integrated with a JBS diode. In FIGS. 3A and 3B, the p-well 310 is configured as having split portions instead of being stretched along an entire width of the device. For example, the p-well 310 are formed to have a non-rectangular planar shape since the Schottky surface 350 is formed at one corner along edges of the device. On the surface of the epi layer 340, a current spreading layer (CSL) 370 is formed. The CSL 370 has different thickness over the epi region. A portion of the CSL 370 extends from the epi region 340 to the bottom surface of the p-well 310. The CSL 370 also has portions extending from the epi region 340 to the same level on which the gate oxide 382 is formed. The portions of the CSL 370 further extending to the same level on which the gate oxide 382 is formed protrude from the portion of the CSL 370 which extends to the bottom surface of the p-well 310. Such protruding portions are located in a JFET region formed between the p-wells 310 and in the Schottky region. The p-well 310 is formed over the CSL 370. With the protruding portions of the CSL 370, the p-well 310 has a non-rectangular planar shape in a unit cell. The p-well 310 does not stretched along an entire width of the device due to the protruding portion of the CSL 370. CSL 370 has the same doping type as layer 360 but doping concentration could be different. The layer 352 protrudes from the CSL 370 layer at the bottom and extends to the Schottky surface 350. This layer has the same doping type as CSL 370 but could have different doping concentration. It could also have either a constant doping or a variable doping that is a function of distance from the Schottky surface 350.

Over the p-well 310, the n+ source region 320 is formed. The n+ source region 320 is restricted within the p-well 310 and forms the source. The p+ body contact region 330 is implanted along the boundary of the p-well 310, extending from the top surface of the n+ source region 320 toward the epi region 340. The region 330 might either remain entirely within region 352 or extend such as to cross the boundary of 352 and 340 to extend into the epi region 340. The p+ body contact region 330 serves the dual purpose of the body contact to the MOSFET and electric field shielding to the JBS diode. Schottky metal, which is deposited on the Schottky surface 350, is deposited on the layer 352 extending over the p+ body contact region 330. Additional metal is then deposited covering the entire area and forming an ohmic contact with the n+ source region 320 and the p+ body contact region 330. The Schottky contact to the layer 352 is thus shorted to the n+ source region 320 and the p+ body contact region 330, which results in a JBS diode between the n+ source region 320 and the drain 360. A gate oxide 382 and a polysilicon gate 384 are formed over the n+ source region 320 and the p+ body contact region 330. The inter-layer dielectric (ILD) layer 390 is deposited over the polysilicon gate 384 and includes oxide, silicon oxide, USG, TEOS, etc. The ILD layer 390 aids in protection of the structure during further processing and prevents the polysilicon gate and source metal deposited over 320 from shorting to each other.

In this design, region 352 on which Schottky surface is arranged has a boundary on the device surface with the p+ body contact region 330 which operates as the shielding region as shown in FIG. 3A. In some implementations, the p-well 310 can be structured such that the region 352 has a boundary on the device surface with p-well 310 as well. In this case, the p-well 310 would extend horizontally below the p+ body contact region 330 covering the p+ body contact region 330 and extend further to the surface of the Schottky surface 350. In other words, the p+ body contact region 330 would be contained within the p-well 310. In an exemplary case, the layer 352 could share a boundary with both the p+ body contact region 330 and the p-well 310 because the edges of p+ body contact region 330 and the p-well 310 coincide at their boundary with region 352. This exemplary case could be a trade-off between performance of the JBS diode achieved through electric field shielding of the Schottky contact by the p+ body contact region 330 and space utilized by the structure. The co-incident boundary of the p+ body contact region 330 and the p-well 310 can be achieved by implanting the dopant ions of the layer 352 and the p-well 310 using an implant mask whose edge in the boundary with Schottky surface 350 remains unchanged between the implants forming the layer 352 and the p-well 310.

In this design as proposed, the MOSFET channel width is not sacrificed while introducing JBS diode. In this regard, there are two trade-offs. Fabrication considerations will necessitate the pitch of MOSFET cells to be increased by the width of the Schottky region. Secondly, MOSFET source resistance will increase because source width is reduced by the introduction of diode. However, both these effects are minor compared to the savings of the die area of a separate JBS diode. These effects are also minor compared to savings of the die area of separate JBS diode areas outside the main MOSFET cell that are monolithically integrated with the MOSFET. The structure incorporating the JBS diode with the MOSFET is still beneficial by avoiding incurring an additional chip area and increasing cost and labor, which are required for the use of external diode. The suggested structures also reduce the number of packages and lower the cost of implementing power converters. By eliminating the parasitic inductance between separately packaged devices, it is possible to improve the efficiency and increase switching frequency of the devices.

The design in FIGS. 3a and 3b allow a part of the MOSFET cell contained within the body contact of the MOSFET cell to be converted to the JBS diode by making relatively simple changes during the process such as changing few masks. In FIGS. 3a and 3b, gate oxide and polysilicon are patterned only in the MOSFET cells and not patterned in the diode cells. To implement the designs in FIGS. 3a and 3b, before forming the ohmic contact on the n+ source and p+ body of the DMOSFET, an oxide can be patterned over the region within the body contact that forms the Schottky contact of the JBS diode to prevent the ohmic contact formation there. The Schottky metal is then patterned in the JBS diode region to form the JBS contact. The overlay metal of the DMOSFET process will be used to electrically connect the anode of the JBS diode to the source of the DMOSFET so that the JBS diode is anti-parallel to the DMOSFET.

This design also allows the flexibility of choosing the proportion of Schottky contact area to the total MOSFET active area based on the device application by changing a few lithographic masks without altering the process or total die area. This device is especially useful for the wide bandgap semiconductors such as SiC or GaN, compared to Si, because the wide bandgap of SiC or GaN devices increases the forward voltage drop of the body diode of SiC MOSFET to ˜4V whereas Si MOSFET's body diode has forward voltage drop ˜1.5V, similar to JBS diode. The suggested device can provide improved device characteristics that can be fabricated from various semiconductor materials. The disclosed structures can be implemented based on various semiconductors with wide bandgap including SiC, GaN and other suitable materials and can also be used to improve Si-based devices.

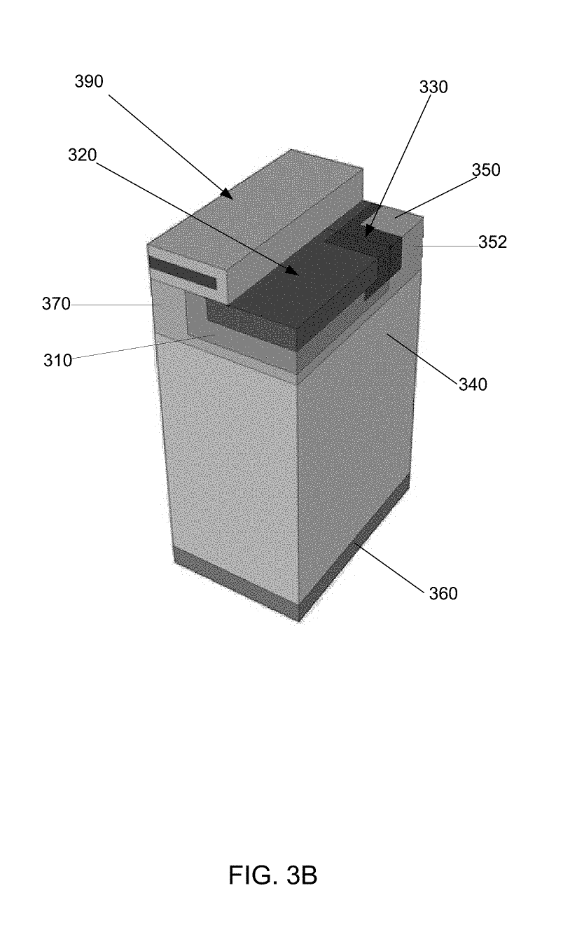

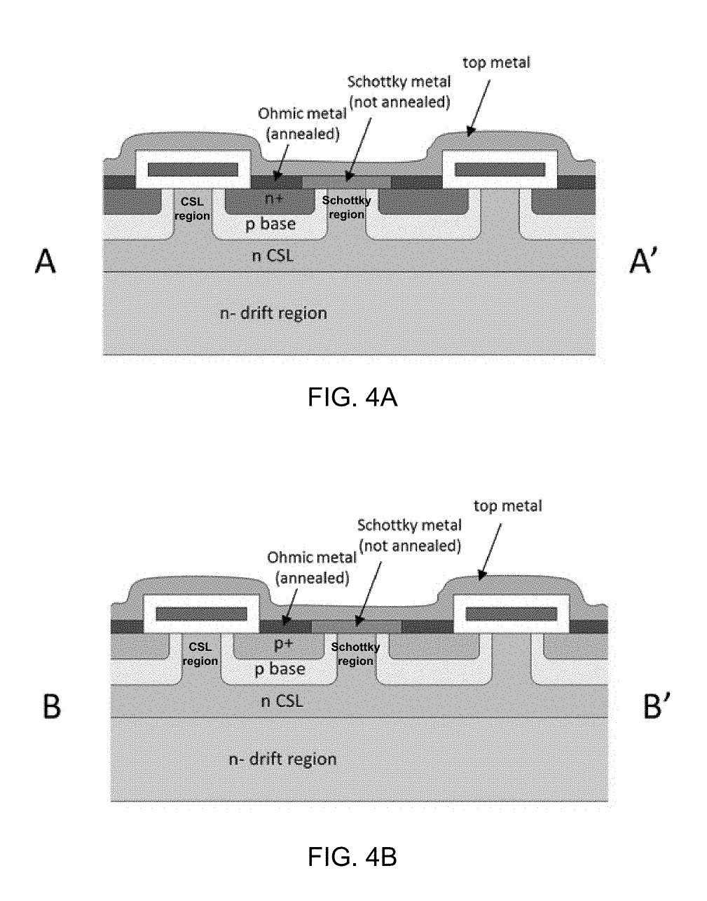

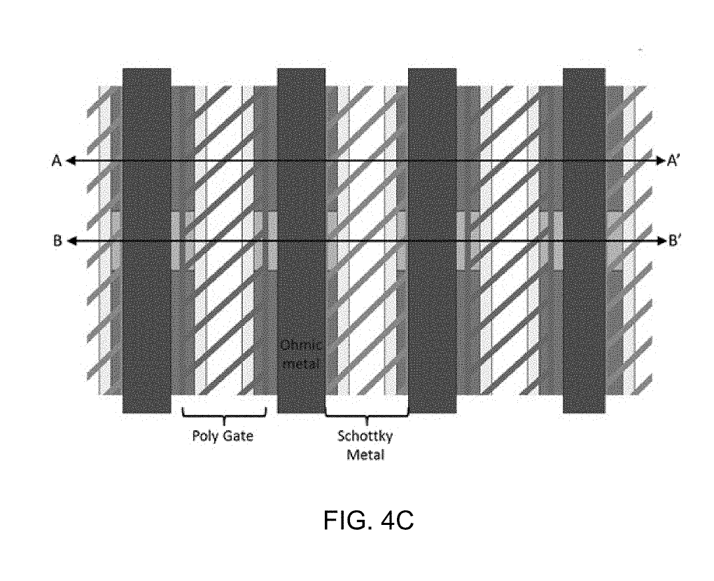

FIGS. 4A, 4B and 4C show another implementation of a semiconductor device having monolithically integrated SiC-DMOSFET and a diode. In the implementation, certain cells or portions of the DMOSFET can be replaced by JBS diodes. FIGS. 4A and 4B are cross-sectional views taken along the lines A-A′ and B-B′ which is indicated in FIG. 4C. The lines A-A′ and B-B′ are across the portions of the DMOSFET-diode integrated device, the portions include the n+ region and p+ region, respectively. The design in FIGS. 4a to 4c allow the proportion of the MOSFET cells to be converted to the JBS diode by making relatively simple changes during the process such as changing few masks. In FIGS. 4a to 4c, gate oxide and polysilicon are patterned only in the MOSFET cells and not patterned in the diode cells. To implement the designs in FIGS. 4a to 4c, before forming the ohmic contact on the n+ source and p+ body of the DMOSFET, an oxide can be patterned over the cells that form the JBS diode to prevent the ohmic contact formation. The Schottky metal is patterned in the JBS diode cells to form the JBS contact. The final overlay metal of the DMOSFET process will be used to electrically connect the anode of the JBS diode to the source of the DMOSFET so that the JBS diode is anti-parallel to the DMOSFET. This device structure uses additional p+ implants in the JBS region for shielding, thus increasing device pitch whereas the structure shown in FIGS. 3a and 3b uses the p-well 310 and p+ body contact region 330 implants already present within the MOSFET cell for JBS anode shielding. Using the p-well and p+ implants within the MOSFET cell for JBS shielding affects the device structure to allow a smaller pitch in the structure in FIGS. 3a and 3b compared to the structure in FIGS. 4a to 4c. Both structures also defines the Schottky contact using lithography in the fabrication process. This device is useful because the wide bandgap of SiC or GaN devices increases the forward voltage drop of the body diode of SiC MOSFET to ˜4V whereas Si MOSFET's body diode has forward voltage drop ˜1.5V, similar to JBS diode.

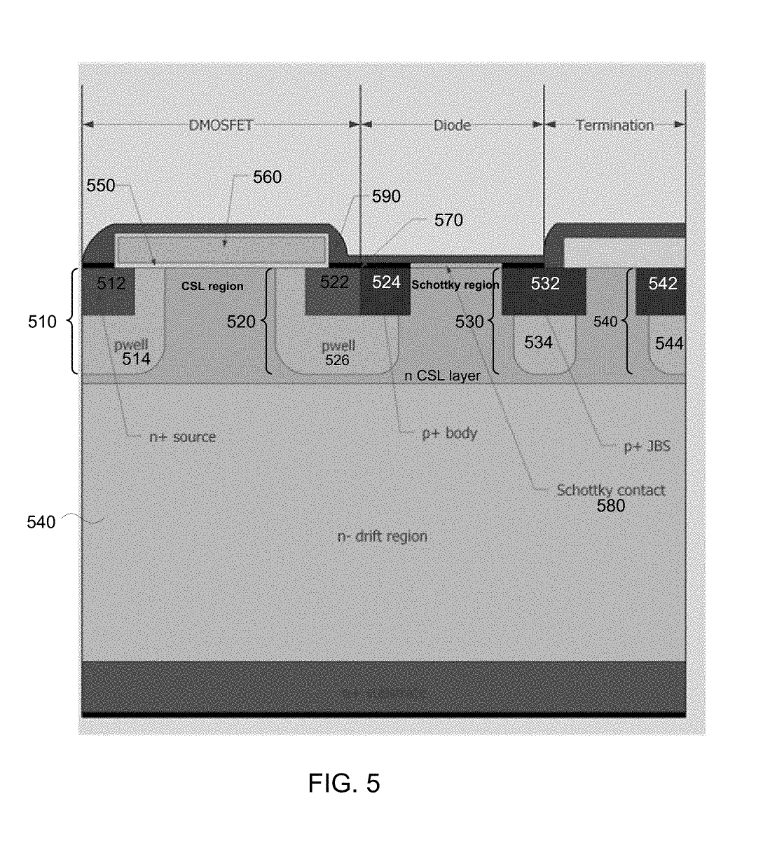

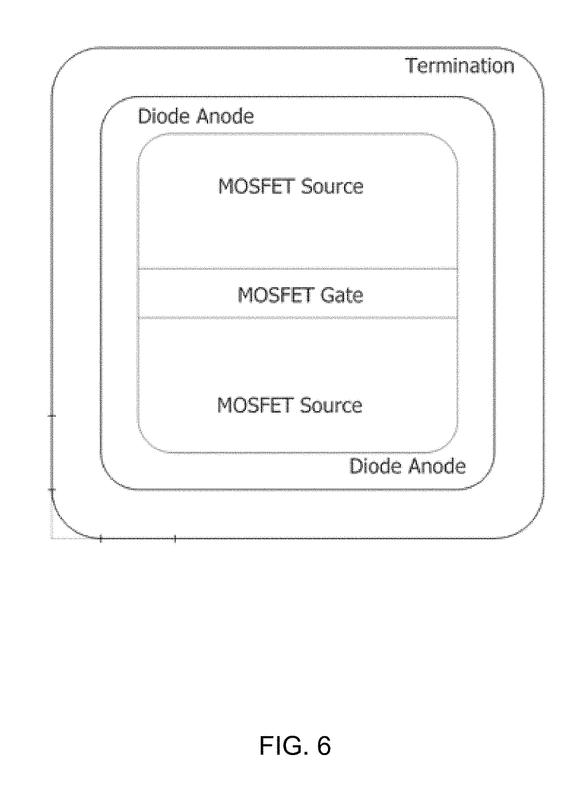

FIGS. 5 and 6 show another implementation of a semiconductor device having monolithically integrated SiC DMOSFET and JBS diode. FIGS. 5 and 6 show a cross-section view and a plan view respectively of the semiconductor device. Referring to FIG. 6, JBS diode cells are added as concentric cells in the region between the DMOSFET active area and the termination area. The cross-sectional view of FIG. 5 shows three different areas, i.e., first to third areas, that are provided for the DMOSFET, JBS diode and termination, respectively from the interior of the device at the left to the exterior of the device at the right. Another version of the device in FIG. 5 could have the diode region at the left (interior of the device), then the MOSFET region in the middle and the termination region at the right (exterior of the device). In both the versions, there are multiple cells of MOSFETs within the MOSFET region, multiple cells of JBS diodes in the JBS diode region and multiple termination rings, of which only one cell of each type is shown in each region. In FIG. 5, the doping regions 510, 520, 530, 540 are arranged in the CSL 544 over the n-drift region 542. A CSL 544 has the same doping type as the n-drift region 542 but doping concentration could be different. For example, the CSL 544 can be more heavily doped than the n-drift region 542 in order to facilitate current spreading. In some implementations, the Schottky region is doped between the drift region 542 and the CSL 544. In some implementations, the CSL 544 and the Schottky region can be omitted, in which case the drift region 542 extends to the area for the omitted CSL and the Schottky region.

Each doping region includes a p-well region 514, 526, 534, 544 and a heavily doped region 512, 522, 524, 532, 542. Heavily doped regions 512 and 522 lie entirely within 514 and 526 respectively. However, heavily doped regions 522, 532 and 542 could either straddle 526, 534 and 544 respectively as shown in FIG. 5 or they could lie entirely within 526, 534 and 544 respectively. In a particular case, the vertical edge of the p-well region 526 in FIG. 5 not shared with the heavily doped region 522 could coincide exactly with a part of the vertical edge of the p-well region 526. Similarly, the vertical edges of the heavily doped region 532 could coincide with a part of the vertical edge of the p-well region 534, and the vertical edges of the heavily doped region 542 could coincide with a part of the vertical edge of the p-well region 544. The doping region 510 includes a n+ source region 512 formed over the p-well region 514. The doping region 520 includes the n+ source region 522 and the p+ body region 524 that are formed over the p-well region 526, and marks the boundary in FIG. 5 between the MOSFET region and diode region. The doping regions 530, 540 include P+ JBS regions 532, 542 formed over the p-well regions 534. The conductivity of the heavily doped region 512, 522, 524, 534, 542 depends on which area a particular heavily doped region is located in. For example, the heavily doped regions 512, 522 located in the first area provided for the DMOSFET has n-type conductivity, the heavily doped regions 524, 532 located in the second area provided for the diode has p-type conductivity, and the heavily doped regions 532, 542 located in the third area provided for the termination has p-type conductivity.

An oxide 550 and a polysilicon gate 560 are formed over the n+ source regions 512 and 522 of the doping regions 510 and 512. The oxide 550 and the polysilicon gate 560 are not formed over the p+ body regions 524 and 532. The ohmic contact 570 is formed over the p+ body regions 524 and 532. The ohmic contact 570 is further extended to an area over the n+ source regions 512 and 522. The Schottky contact 580 is formed over a space between the doping regions 520 and 530. An interlayer dielectric layer is formed to cover the oxide 550 and the polysilicon gate 560 and the overlay metal 590 is formed to cover the device.

The p-well 526, 534 and the p+ body regions 524, 532 of the DMOSFET are used as JBS shielding implants. The Schottky region 580 is covered by oxide during the process step when source and body ohmic contacts are formed. The JBS window is then opened and Schottky metal deposited to provide the Schottky contact 580. An overlay metal 590 is formed to connect the MOSFET source and the diode anode. In this design, the pitch of DMOSFET cells don't increase to accommodate the diode, but overall active area increases compared to the design in FIGS. 3a and 3b. Using the p-well for JBS shielding within the MOSFET cell affects device structure to allow a smaller pitch in the structure in FIGS. 3 and 4 compared to the structure in FIG. 5. Both structures also defines the Schottky contact using lithography in the fabrication process.

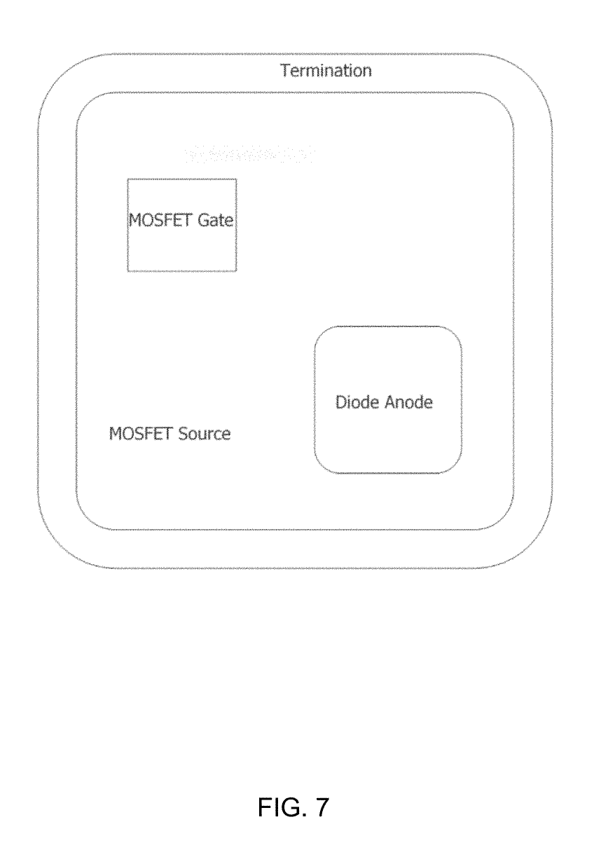

In implementations, the JBS diode can be laid out between the DMOSFET and the termination. In other implementations, different layouts of the DMOSFET and diode may be used, for example with JBS diode stripes at the center and circular DMOSFET rings between diode and termination. In general, JBS diode and DMOSFET can be laid out separately, but share the same termination region. FIG. 7 shows a top view of another exemplary semiconductor device where a DMOSFET and a JBS diode are arranged differently from FIG. 6. In FIG. 7, the DMOSFET is arranged in a peripheral area of the JBS diode, while the DMOSFET and the JBS diode share the termination. For the cross-sectional view of FIG. 7, the locations of the diode area and the transistor area of FIG. 5 can be changed each other, while the termination area is maintained to surround the both of the diode area and the transistor area. When a unipolar mode diode is monolithically integrated in a MOSFET structure on a single chip, both MOSFET and the diode not only share the forward conducting layer but also share the edge termination region such that a significant reduction in an wafer area can be expected.

While this patent document contains many specifics, these should not be construed as limitations on the scope of any invention or of what may be claimed, but rather as descriptions of features that may be specific to particular embodiments of particular inventions. For example, although SiC is discussed as semiconductor materials in some implementations, the implementations are not limited to SiC and other semiconductor materials having a bandgap wider than that of Si are used for the implementations. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed are techniques and structures as described and shown, including:

1. A semiconductor device including:
a substrate including semiconductor materials;
a drift region formed over the substrate;
doping regions formed on a surface of the drift region and including a first impurity region and a second impurity region formed over the first impurity region;
a body contact formed adjacent to the second impurity region;
a Schottky region formed adjacent to the body contact such that the second impurity region and the Schottky region are located on opposite sides of the body contact, the Schottky region contacting the drift region; and
a gate region formed over the doping regions.

2. The semiconductor device of claim 1, wherein the first impurity region include a p-well region and the second impurity region includes an n+ source region.

3. The semiconductor device of claim 1, wherein the first impurity region has a non-rectangular planar shape in a unit cell.

4. The semiconductor device of claim 1, further comprising a current spreading layer is formed over the drift region and has a protruding portion extending along a direction perpendicular to a surface of the substrate.

5. The semiconductor device of claim 4, the protruding portion extends from the drift region to a level same as top surfaces of the doping regions and the body contact.

6. The semiconductor device of claim 4, the protruding portion is located in a JFET (junction field effect transistor) region between the doping regions.

7. The semiconductor device of claim 4, the protruding portion is located in the Schottky region.

8. The semiconductor device of claim 1, wherein the first impurity region, the second impurity region, the body contact, and the Schottky region are arranged on first impurity region does not extend along an entire width of the device.

9. The semiconductor device of claim 1, wherein the semiconductor materials include SiC or GaN.

10. The semiconductor device of claim 1, wherein the Schottky region is shorted to the body contact and the second impurity region.

11. The semiconductor device of claim 1, wherein the doping region provides a channel region adjacent to the second impurity region along a first direction parallel to a surface of the substrate and between the gate region and the drift region along a second direction perpendicular to the first direction.

12. The semiconductor device of claim 1, wherein the drift region is doped with a same doping type as the second impurity region.

13. The semiconductor device of claim 1, wherein the second impurity region is contained within the first impurity region.

14. The semiconductor device of claim 1, wherein the first impurity region is structured to extend horizontally below the second impurity region and further extend to a surface of the Schottky surface.

15. A semiconductor device, including:
a transistor region having a gate region and a source region formed on a side of the gate region, the gate region including a gate formed over a first doping region, a second doping region, and a junction field effect transistor (JFET) region formed between the first doping region and the second doping region; and
a diode region formed over the second doping region and a third doping region, the diode region including an Ohmic contact formed over the second doping region and the third doping region and a Schottky contact formed over an area between the second doping region and the third doping region; and
a termination region surrounding the diode region and the transistor region.

16. The semiconductor device of claim 15, wherein the transistor region, the diode region, and the termination region are concentrically arranged in a same plane.

17. The semiconductor device of claim 15, wherein the diode region is arranged between the transistor region and the termination region.

18. The semiconductor device of claim 15, wherein the transistor region is arranged between the diode region and the termination region.

19. The semiconductor device of claim 15, wherein the second doping region includes a first portion and a second portion that are included in the transistor region and the diode region, respectively.

20. The semiconductor device of claim 19, wherein the first portion of the second doping region includes a n+ source region and the second portion of the second doping region includes a p+ body region.

21. The semiconductor device of claim 15, wherein the first doping region includes a p-well and a n+ source region.

22. The semiconductor device of claim 15, wherein the third doping region includes a p-well and a p+ body region.

23. A semiconductor device, including:
a semiconductor substrate doped with a first-type conductivity with a first concentration;
a drift region formed over the semiconductor substrate and has the first-type conductivity with a second concentration smaller than the first concentration, the drifting region including a first area and a second area that are adjacent each other;
doping regions formed in the drift region to be spaced apart from one another, each doping region including a p-well region;
a gate formed over the first area of the drift region; and
a Schottky contact formed over the second area of the drift region, and
wherein the doping region further includes heavily doped regions over the p-well regions such that a particular heavily doped region has the first-type conductivity or a second-type conductivity different from the first-type conductivity depending on whether the particular heavily doped region is located in the first area or the second area.

24. The semiconductor device of claim 23, wherein the drifting region further includes a third area over which a termination is provided.

25. The semiconductor device of claim 23, wherein a junction field effect transistor (JFET) region is formed over the first area of the drift region.

26. The semiconductor device of claim 23, wherein a current spreading layer is formed in the drift region to have the first-type conductivity.

27. The semiconductor device of claim 23, further comprising an ohmic contact between the gate and the Schottky contact and over the doping regions.

28. The semiconductor device of claim 23, the semiconductor substrate includes materials having a bandgap wider than that of silicon.
